(19) United States
(12) Patent Application Publication
(10) Pub. No.: US 2026/0105210 A1
(43) Pub. Date: Apr. 16, 2026

(54) CHEMICAL MECHANICAL POLISHING (CMP) SIMULATION METHOD AND SYSTEM, AND NON-TRANSITORY COMPUTER READABLE MEDIUM STORING COMPUTER PROGRAM FOR PERFORMING CMP SIMULATION

(71) Applicant: Samsung Electronics Co., Ltd., Suwon-si (KR)

(72) Inventors: Hyun Seop LEE, Busan-si (KR); Yon Sang CHO, Busan-si (KR); Joo Cheol HAN, Suwon-si (KR); Myeong Jun KIM, Suwon-si (KR); Hyun Ki KIM, Suwon-si (KR); Hong Jin KIM, Suwon-si (KR); Mun Young HONG, Suwon-si (KR)

(73) Assignees: Samsung Electronics Co., Ltd., Suwon-si (KR); Dong-A University Research Foundation For Industry-Academy Cooperation, Busan (KR)

(21) Appl. No.: 19/213,164

(22) Filed: May 20, 2025

(30) Foreign Application Priority Data
Oct. 10, 2024 (KR) 10-2024-0137642
Jan. 21, 2025 (KR) 10-2025-0008864

(51) Int. Cl. G06F 30/17

(52) U.S. Cl. CPC G06F 30/17

(57) ABSTRACT

There is provided a CMP simulation method performed by a computing device. The method may comprise: inputting a first process condition on a chemical mechanical polishing (CMP) process to an artificial intelligence model, wherein the artificial intelligence model has been trained to receive a process condition of the CMP process and predict and output a material removal rate (MRR) profile based on the received process condition; calculating a similarity between a preset target MRR profile and an output corresponding to the first process condition of the artificial intelligence model; in response to that the similarity is equal to or greater than a predetermined threshold value, determining the first process condition as a process condition of the CMP process; and in response to that the similarity is smaller than the threshold value, inputting a second process condition different from the first process condition to the artificial intelligence model.

### CROSS-REFERENCE TO RELATED APPLICATION

This application claims priority and all the benefits accruing therefrom under 35 U.S.C. § 119 from Korean Patent Application No. 10-2024-0137642, filed on Oct. 10, 2024, and Application No. 10-2025-0008864, filed on Jan. 21, 2025, in the Korean Intellectual Property Office, the entire contents of both of which are herein incorporated by reference.

### BACKGROUND

### Field

The present disclosure relates to a chemical mechanical polishing (CMP) simulation method, a CMP simulation system, and a non-transitory computer-readable medium including a computer program for performing a CMP simulation, and more particularly, to a method for predicting a material removal rate (MRR) process condition from an MRR profile or predicting an MRR profile from a CMP process condition based on an artificial intelligence model.

### Description of Related Art

In a process of manufacturing a semiconductor apparatus, a CMP process is widely used as a planarization technology for removing a step between layers formed on a substrate. The CMP process is a process of efficiently planarizing films formed on the substrate by injecting a polishing slurry including abrasive particles between the substrate and a polishing pad and rubbing the polishing pad against the substrate.

In the CMP process, an effect of various process conditions such as a pressure onto each area of the wafer or a retainer ring pressure, a rotation speed of a platen or a carrier, a slurry flow rate, etc. on the MRR profile was based on the Preston equation. However, such a conventional simulation technique does not take into account the complex influence of the process condition of the CMP process on the MRR profile, and is less versatile because it depends only on a predetermined CMP apparatus and its design.

### SUMMARY

A technical purpose to be achieved through an embodiment of the present disclosure is to provide a method for determining an optimal CMP process condition using an artificial intelligence model trained to predict an MRR profile based on various CMP process conditions.

The technical purposes of the present disclosure are not limited to the technical purposes mentioned above, and other technical purposes not mentioned may be clearly understood by those skilled in the art from the following description.

There is provided a chemical mechanical polishing (CMP) simulation method performed by a computing device. The method may comprise: inputting a first process condition on a CMP process to an artificial intelligence model, wherein the artificial intelligence model has been trained to receive a process condition of the CMP process and predict and output a material removal rate (MRR) profile based on the received process condition; calculating a similarity between a preset target MRR profile and an output corresponding to the first process condition of the artificial intelligence model; in response to calculating that the similarity is equal to or greater than a predetermined threshold value, determining the first process condition as the process condition of the CMP process; and in response to calculating that the similarity is smaller than the predetermined threshold value, inputting a second process condition different from the first process condition to the artificial intelligence model.

There is provided a chemical mechanical polishing (CMP) simulation system. The system may comprise: a processor; and a memory for storing instructions therein. When the instructions are executed by the processor, the instructions may cause the processor to: input a first process condition on a CMP process to an artificial intelligence model, wherein the artificial intelligence model has been trained to receive a process condition of the CMP process and predict and output a material removal rate (MRR) profile based on the received process condition; calculate a similarity between a preset target MRR profile and an output corresponding to the first process condition of the artificial intelligence model; in response to calculating that the similarity is equal to or greater than a predetermined threshold value, determine the first process condition as a process condition of the CMP process; and in response to calculating that the similarity is smaller than the predetermined threshold value, input a second process condition different from the first process condition to the artificial intelligence model.

There is provided a non-transitory computer-readable medium storing therein a computer program. When the computer program is executed by a processor, the processor may be configured to: input a first process condition on a chemical mechanical polishing (CMP) process to an artificial intelligence model, wherein the artificial intelligence model has been trained to receive a process condition of the CMP process and predict and output a material removal rate (MRR) profile based on the received process condition; calculate a similarity between a preset target MRR profile and an output corresponding to the first process condition of the artificial intelligence model; in response to calculating that the similarity is equal to or greater than a predetermined threshold value, determine the first process condition as the process condition of the CMP process; and in response to calculating that the similarity is smaller than the predetermined threshold value, input a second process condition different from the first process condition to the artificial intelligence model.

There is provided a chemical mechanical polishing (CMP) simulation method performed by a computing device. The method may comprise: inputting a target material removal rate (MRR) profile of a CMP process to a first artificial intelligence model, wherein the first artificial intelligence model has been trained to receive a MRR profile of the CMP process and predict and output a process condition based on the received MRR profile; inputting a first process condition output from the first artificial intelligence model to a second artificial intelligence model, wherein the second artificial intelligence model has been trained to receive a process condition of the CMP process and predict and output an MRR profile based on the received process condition; calculating a similarity between the target MRR profile and an output corresponding to the first process condition of the second artificial intelligence model; and in response to that the similarity is equal to or greater than a predetermined threshold value, determining the first process condition as the process condition of the CMP process.

Specific details of other embodiments are included in the detailed description and drawings.

### BRIEF DESCRIPTION OF DRAWINGS

The above and other aspects and features of the present disclosure will become more apparent by describing in detail embodiments thereof with reference to the attached drawings, in which:

FIG. 1 is a plan view illustrating a polishing facility including a chemical mechanical polishing apparatus according to some example embodiments;

FIG. 2 is a perspective view illustrating a chemical mechanical polishing apparatus according to some example embodiments;

FIG. 3 is a block diagram illustrating a computing device for performing a semiconductor design according to an example embodiment;

FIG. 4 illustrates an artificial intelligence model for performing CMP simulation according to an example embodiment of the present disclosure;

FIG. 5 is an example flowchart illustrating a CMP simulation method according to an example embodiment;

FIG. 6 is a flowchart specifically illustrating a step of inputting a second process condition of FIG. 5 into an artificial intelligence model;

FIG. 7 is an example flowchart illustrating an CMP simulation method according to another example embodiment of the present disclosure;

FIG. 8 is a flowchart specifically illustrating a step of inputting a first process condition of FIG. 5 into an artificial intelligence model;

FIG. 9 is an example flowchart illustrating a CMP simulation method according to still another example embodiment of the present disclosure; and

FIGS. 10A and 10B illustrates an example graphical user interface (GUI) on which a CMP simulation method according to an example embodiment of the present disclosure is performed.

### DETAILED DESCRIPTIONS

Hereinafter, preferred embodiments of the present disclosure will be described in detail with reference to the attached drawings. Advantages and features of the present disclosure, and a method of achieving the advantages and features will become apparent with reference to embodiments described later in detail together with the accompanying drawings. However, embodiments of the present disclosure are not limited to the embodiments as disclosed below, but may be implemented in various different forms. Thus, these embodiments are set forth only to make the present disclosure complete, and to inform the scope of the present disclosure to those of ordinary skill in the technical field to which the present disclosure belongs, and the present disclosure is only defined by the scope of the claims.

The same reference numbers in different drawings represent the same or similar elements, and as such perform the same functionality unless otherwise noted. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure the gist of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise.

Additionally, in describing the components of the present disclosure, terms such as first, second, A, B, a, and b may be used. These terms are only used to distinguish one component from another component, and the nature, sequence, order, or number of the component are not limited by the term. It should be understood that when a component is described as being “connected,” “coupled,” or “combined” to another component, the component may be directly connected, coupled, or combined to another component, still another component may be “interposed” therebetween, and thus the component may be connected, coupled, or combined to another component via the sill another component.

It will be further understood that the terms “comprise”, “comprising”, “include”, and “including” as used herein specify the presence of the stated features, steps, operations, elements, and/or components, but do not preclude the presence or addition of one or more other features, steps, operations, elements, components, and/or portions thereof.

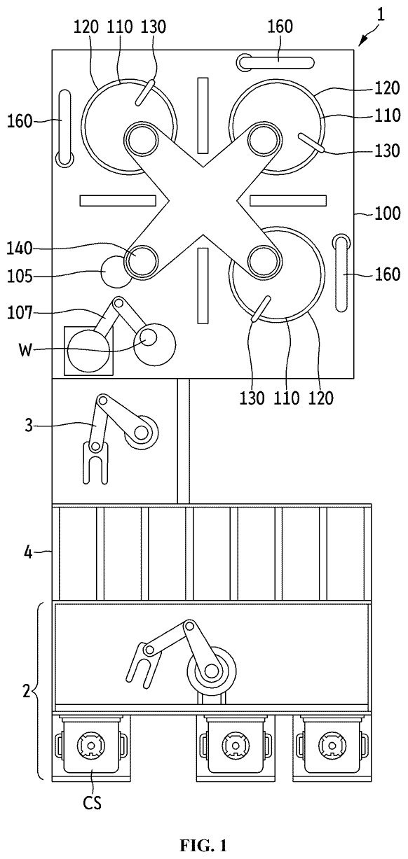

FIG. 1 is a plan view illustrating a polishing facility including a chemical mechanical polishing apparatus according to some example embodiments. Referring to FIG. 1, the polishing facility may include a chemical mechanical polishing apparatus 1, an index unit 2, a transfer robot 3, and a cleaning apparatus 4.

The chemical mechanical polishing apparatus 1 may perform a polishing process on a wafer W. In some embodiments, the chemical mechanical polishing apparatus 1 may include a lower base 100, a polishing pad 110, a platen 120, a slurry supply 130, a carrier head assembly 140, and a pad conditioner 160 disposed on the lower base 100.

The index unit 2 may provide a space in which a cassette CS in which the wafers W are accommodated is placed. The index unit 2 may take out the wafer W from the cassette CS and transfer the wafer W to the transfer robot 3, or may bring the wafer W on which the polishing process has been completed into the cassette CS.

The transfer robot 3 may be provided between the chemical mechanical polishing apparatus 1 and the index unit 2. The transfer robot 3 may transfer the wafer W between the chemical mechanical polishing apparatus 1 and the index unit 2. In one example, a load cup 105 adjacent to the transfer robot 3 may be disposed in the chemical mechanical polishing apparatus 1. The load cup 105 may provide a space in which the wafer W temporarily waits. For example, the wafer W may be held temporarily in a space in the load cup 105. In addition, an exchanger 107 may be provided between the transfer robot 3 and the load cup 105. The exchanger 107 may transfer the wafer W transferred from the index unit 2 by the transfer robot 3 to the load cup 105 or transfer the wafer W disposed on the load cup 105 to the transfer robot 3.

The cleaning apparatus 4 may be provided between the index unit 2 and the transfer robot 3. The wafer W polished by the chemical mechanical polishing apparatus 1 may be disposed on the load cup 105. The wafer W disposed on the load cup 105 may be transferred to the cleaning apparatus 4 by the transfer robot 3 disposed adjacent to the load cup 105. The cleaning apparatus 4 may clean contaminants remaining on the polished wafer W. The cleaned wafer W may be transferred to the index unit 2 and received in the cassette CS. Accordingly, the polishing process on the wafer W may be completed.

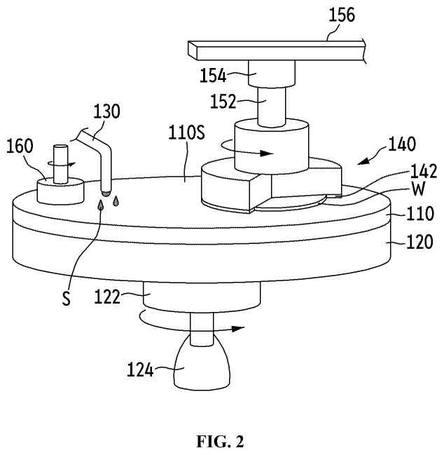

FIG. 2 is a perspective view illustrating a chemical mechanical polishing apparatus according to some example embodiments. Referring to FIG. 2, the chemical mechanical polishing apparatus may include the polishing pad 110, the platen 120, the slurry supply 130, the carrier head assembly 140, and the pad conditioner 160.

The polishing pad 110 may be disposed on the platen 120. The polishing pad 110 may be provided in a form of a plate having a predetermined thickness, for example, a circular plate. However, the present disclosure is not limited thereto. The polishing pad 110 may include a polishing surface 110S facing the wafer W. The polishing surface 110S may have a predetermined roughness. For example, the polishing surface 110S may have irregularities. While the polishing process is performed, the polishing surface 110S may be in contact with the wafer W to polish the wafer W.

The polishing pad 110 may include a plurality of grooves. The grooves may be formed in the polishing surface 110S of the polishing pad 110. For example, each of the grooves may be recessed from the polishing surface 110S into the pad 110. While the polishing process is performed, the grooves may be provided as a channel of the polishing slurry S to facilitate the flow of the polishing slurry S.

The platen 120 may support the polishing pad 110. For example, the polishing pad 110 may be disposed on an upper surface of the platen 120. In addition, the platen 120 may be rotatable. The rotatable platen 120 may rotate the polishing pad 110 disposed on the platen 120. For example, a first drive shaft 122 connected to a bottom of the platen 120 may rotate upon receiving a rotational power from a first motor 124. The platen 120 may rotate the polishing pad 110 around a rotation axis perpendicular to the upper surface of the platen 120.

The slurry supply 130 may be disposed adjacent to the polishing pad 110. While the polishing process is performed, the slurry supply 130 may supply the polishing slurry S onto the polishing surface 110S of the polishing pad 110. The polishing slurry S may be smoothly supplied to between the wafer W and the polishing pad 110 through the grooves formed in the polishing surface 110S.

In some embodiments, the polishing slurry S may include a plurality of abrasive particles. For example, the polishing slurry S may include a reactant in which the abrasive particles are dispersed and/or a chemical reaction catalyst. The abrasive particles may function as an abrasive. For example, the abrasive particles may include a metal oxide, a metal oxide coated with an organic material or an inorganic material, or a metal oxide in a colloidal state. For example, the abrasive particles may include at least one of silica, alumina, ceria, titania, zirconia, magnesia, germania, mangania, and combinations thereof. However, the present disclosure is not limited thereto.

The carrier head assembly 140 may be disposed adjacent to the polishing pad 110. The carrier head assembly 140 may provide the wafer W on the polishing surface 110S of the polishing pad 110. For example, the carrier head assembly 140 may operate to hold the wafer W against the polishing pad 110.

In some embodiments, the carrier head assembly 140 may independently control polishing parameters (e.g., pressure, etc.) related to each of wafers W. For example, the carrier head assembly 140 may include a retaining ring 142 for holding the wafer W under a flexible membrane. This carrier head assembly 140 may include a plurality of independently controllable pressurizable chambers defined by the flexible membrane. The pressurizable chambers may apply independently controllable pressure to related areas on the flexible membrane or related areas on the wafer W.

The carrier head assembly 140 may be rotatable. The rotatable carrier head assembly 140 may rotate the wafer W fixed to the carrier head assembly 140. For example, a second drive shaft 152 connected to a top of the carrier head assembly 140 may rotate upon receiving rotational power from a second motor 154.

The carrier head assembly 140 may be supported by a support structure 156. The support structure 156 may be, for example, a carousel or a track. However, the present disclosure is not limited thereto. In some embodiments, the carrier head assembly 140 may laterally translate across the upper surface of the polishing pad 110. For example, the carrier head assembly 140 may vibrate on a slider of the support structure 156, or under rotational vibration of the support structure 156 itself, or the like.

In FIG. 2, only one carrier head assembly 140 is provided on the polishing pad 110. However, this is only an example. In another example, in order to efficiently use the surface area of the polishing pad 110, a plurality of carrier head assemblies 140 may be provided on the polishing pad 110. In addition, in FIG. 2, a rotation direction of the platen 120 and a rotation direction of the carrier head assembly 140 are shown to be the same as each other. However, this is only an example, and the platen and the carrier head assembly may rotate in different rotation directions.

The pad conditioner 160 may be disposed adjacent to the polishing pad 110. The pad conditioner 160 may perform a conditioning process on the polishing surface 110S of the polishing pad 110. Accordingly, the pad conditioner 160 may stably maintain the polishing surface 110S of the polishing pad 110 so that the wafer W is effectively polished during the polishing process.

The CMP process performed in the chemical mechanical polishing apparatus described with reference to FIGS. 1 and 2 may be referred to as a process of planarizing a specific film on a semiconductor wafer, and in the CMP process, the evenness of the polished surface after the polishing is very important. A rate at which the film of the wafer is cut, that is, the film removal rate, is referred to as a material removal rate (MRR). The distribution of MRR at any measurement point of the wafer is referred to as a MRR profile. The MRR profile may include the actual MRR measured throughout the wafer, or a normalized MRR obtained by normalizing the MRR of each measurement point based on an average value, a maximum value, or a minimum value of the total MRR measured in the wafer. In general, since the MRR profile has a concentric circle shape around a center of the wafer, it is expressed based on the distance from the center of the wafer.

Obtaining a target MRR profile in the CMP process may be directly related to improving the yield of the semiconductor manufacturing process. Therefore, there is a need for a method for optimizing CMP process conditions capable of obtaining the target MRR profile. For example, the CMP process conditions may include, but are not limited to, the pressure of the retaining ring, the pressure per zone of the wafer, the rotational speed of the platen, the rotational speed of the carrier, and the slurry flow rate. In the present disclosure, the CMP simulation may include deriving the CMP process conditions for obtaining the target MRR profile as described above, or predicting the MRR profile under the CMP process conditions. Hereinafter, embodiments related to the CMP simulation will be described in detail.

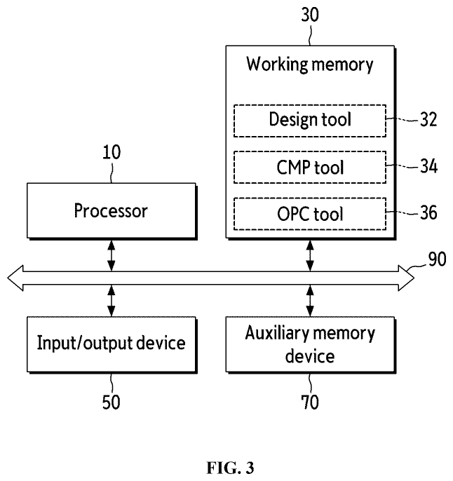

FIG. 3 is a block diagram illustrating a computing device for performing a semiconductor design according to an example embodiment.

Referring to FIG. 3, the computing device may include a processor 10, a working memory 30, an input/output device 50, and an auxiliary memory device 70. The computing device of FIG. 3 may be provided as a device dedicated to the CMP simulation of the present disclosure, and may include various design and validation simulation programs.

The processor 10 may execute software (an application program, an operating system, and device drivers) to be executed in the computing device. In example embodiments, the processor 10 may be a central processing unit (CPU). In still further example embodiments, the processor 10 may be a plurality of processors 10. The processor 10 may execute an OS (not shown) loaded into the working memory 30. The processor 10 may execute various application programs to be executed based on the operating system (OS). For example, the processor 10 may execute a layout design tool 32, a CMP tool 34, and/or an optical proximity correction (OPC) tool 36 loaded into the working memory 30. In another example, the computing device of the present disclosure may include a processor other than a CPU. For example, the processor 10 may comprise one or more of a graphics processing unit (GPU), an application processing unit (APU), an application specific integrated circuit (ASIC), a graphic processing unit (GPU) chip, an application processor (AP) chip, an application specific integrated circuit (ASIC), a digital signal processor (DSP), or other processing units.

The operating system (OS) or the application programs may be loaded into the working memory 30. In booting the computing device, an OS image (not shown) stored in the auxiliary memory device 70 may be loaded into the working memory 30 based on a booting sequence. All input/output operations of the computing device may be supported by the operating system OS. The application programs may be selected by a user or loaded into the working memory 30 to provide a basic service. The design tool 32, the CMP tool 34, and/or the OPC tool 36 may be loaded into the working memory 30 from the auxiliary memory device 70.

The design tool 32 may have a bias function capable of changing a shape and a position of specific layout patterns to be different from those defined by a design rule. In addition, the design tool 32 may perform a Design Rule Check (DRC) under the changed bias data condition.

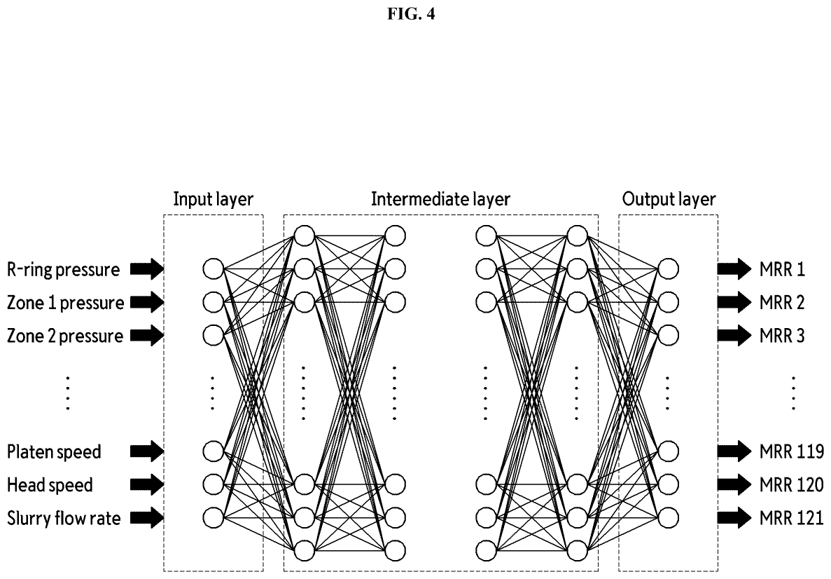

The CMP tool 34 may predict a CMP process condition for obtaining a target MMR profile via the CMP simulation, or predict an MMR profile according to any CMP process condition. In more detail, the CMP tool 34 according to an embodiment of the disclosure may input a first process condition of the CMP process to an artificial intelligence model. In this regard, the artificial intelligence model may be a model trained to receive the process conditions of the CMP process (e.g., a pressure of a retaining ring, pressure on each area of a wafer, a rotation speed of a platen, a rotation speed of a carrier, a slurry flow rate, etc.) and predict and output the MRR profile based on the received process conditions. When the CMP tool 34 is executed, the artificial intelligence model and the CMP tool may be loaded together in the working memory 30. A configuration of the artificial intelligence model will be described later with reference to FIG. 4.

The artificial intelligence model may receive the first process condition, and predict the MRR profile based on the first process condition, and output the predicted MRR profile. The CMP tool 34 may compare a preset target MRR profile with the output related to the first process condition from the artificial intelligence model to calculate the similarity between the target MRR profile and the output from the artificial intelligence model. For example, the similarity may be calculated based on a geometric distance (e.g., Euclidean distance) between the target MRR profile and the MRR profile output from the artificial intelligence model, or may be calculated using cosine similarity. However, the present disclosure is not limited thereto, and the similarity between the target MRR profile and the output of the artificial intelligence model may be calculated using any of the methods used to calculate the similarity between two vectors.

In some embodiments, the similarity between the target MRR profile and the output of the artificial intelligence model may correspond to a prediction accuracy of the artificial intelligence model. Although following embodiments are described on the assumption that the similarity between the target MRR profile and the output of the artificial intelligence model corresponds to the prediction accuracy of the artificial intelligence model, this assumption may be applied to a case in which the similarity is calculated in another scheme.

In some embodiments, calculating the prediction accuracy of the artificial intelligence model may include calculating a correlation coefficient between the target MRR profile and the output corresponding to the first process condition of the artificial intelligence model. Alternatively, in some further embodiments, calculating the prediction accuracy of the artificial intelligence model may include applying a linear regression to the target MRR profile and the output corresponding to the first process condition of the artificial intelligence model to calculate an R-squared value.

When the calculated prediction accuracy is equal to or greater than a predetermined threshold value, this means that the similarity between the MRR profile predicted by the artificial intelligence model and the target MRR profile is equal to or greater than a predetermined level, and thus the CMP tool 34 may determine the first process condition first input to the artificial intelligence model as the process condition of the CMP process. When the prediction accuracy is the correlation coefficient, the threshold value may be an arbitrary correlation coefficient. Alternatively, when the prediction accuracy is the R-squared value, the threshold value may be an arbitrary R-squared value. The predetermined threshold value may be defined in advance of the operations disclosed herein and may be stored in, for example, the working memory 30 or the auxiliary memory device 70.

On the other hand, when the calculated prediction accuracy is smaller than the predetermined threshold value, this means that the MRR profile predicted by the artificial intelligence model is not approximate to the target MRR profile. This may mean that the first process condition may not be used as the process condition of the CMP process, and thus the CMP tool 34 may input a second process condition different from the first process condition to the artificial intelligence model.

In some embodiments, the CMP tool 34 may input the output corresponding to the first process condition of the artificial intelligence model as a feedback to the artificial intelligence model, and the artificial intelligence model may output the second process condition such that the prediction accuracy is equal to or greater than the threshold value, based on the input feedback. The CMP tool 34 may input the output second process condition back to the artificial intelligence model. After, as described above, the second process condition is input to the artificial intelligence model, the prediction accuracy of the artificial intelligence model may be calculated again according to the above-described embodiments. Then, whether the second process condition is determined as the process condition of the CMP process or a new process condition is input to the artificial intelligence model may be determined again, based on the calculated prediction accuracy.

Alternatively, in some further embodiments, prior to inputting the second process condition different from the first process condition to the artificial intelligence model, the CMP tool 34 may adjust some of the parameters of the artificial intelligence model and re-train the artificial intelligence model based on the adjustment result. The CMP tool 34 may input the output corresponding to the first process condition of the artificial intelligence model as the feedback to the artificial intelligence model, and then, the artificial intelligence model may output a parameter of the artificial intelligence model which allows the prediction accuracy to be equal to or greater than the threshold value, based on the input feedback. The CMP tool 34 may adjust the artificial intelligence model based on the obtained parameter, and then input the new second process condition thereto. In some cases, the CMP tool 34 may perform only the adjustment of the artificial intelligence model and subsequently, input the first process condition that was initially input to the artificial intelligence model again to the artificial intelligence model.

In some still further embodiments, in order to determine the first process condition to be initially input, the CMP tool 34 may additionally use another artificial intelligence model trained to receive the MRR profile and predict and output the process condition based on the received MRR profile. The CMP tool 34 may determine the process condition obtained by inputting the target MRR profile into the artificial intelligence model for predicting the process condition as the first process condition.

In some still further embodiments, the CMP tool 34 may obtain the first process condition by inputting the target MRR profile to a first artificial intelligence model trained to receive the MRR profile and predict and output the process condition of the CMP process as described above, and then may input the obtained first process condition to a second artificial intelligence model trained to receive the process condition of the CMP process and predict and output the MRR profile based on the received process condition. The CMP tool 34 may then compare the target MRR profile with an output corresponding to the first process condition of the second artificial intelligence model and calculate the prediction accuracy of the first artificial intelligence model based on the comparing result. As described above, the prediction accuracy may be calculated as any one of the correlation coefficient or the R-squared value of the linear regression analysis. When the calculated prediction accuracy is equal to or greater than the preset threshold value, the CMP tool 34 may determine the first process condition as the process condition of the CMP process.

The computing device of FIG. 3 may be connected to the chemical mechanical polishing apparatus of FIGS. 1 to 2, and the CMP tool 34 may control the chemical mechanical polishing apparatus using the process condition determined via the above-described CMP simulation.

The OPC tool 36 may perform optical proximity correction (OPC) on the layout data output from the design tool 32.

For example, the working memory 30 may be a volatile memory such as a dynamic random access memory (DRAM), a static random access memory (SRAM), or the like, or a non-volatile memory such as a flash memory, a phase change random access memory (PRAM), a resistance random access memory (RRAM), a nano floating gate memory (NFGM), a polymer random access memory (PoRAM), a magnetic random access memory (MRAM), a ferroelectric random access memory (FRAM), or the like.

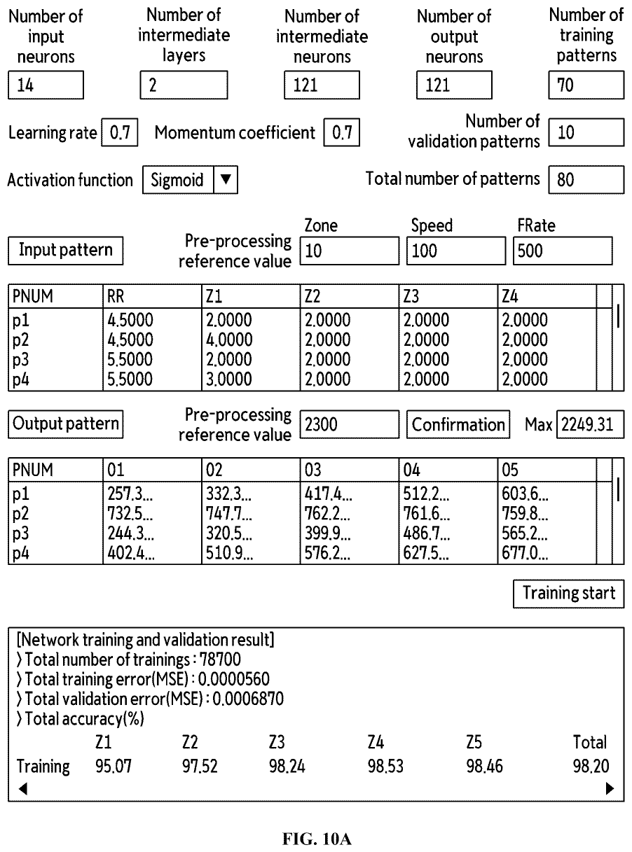

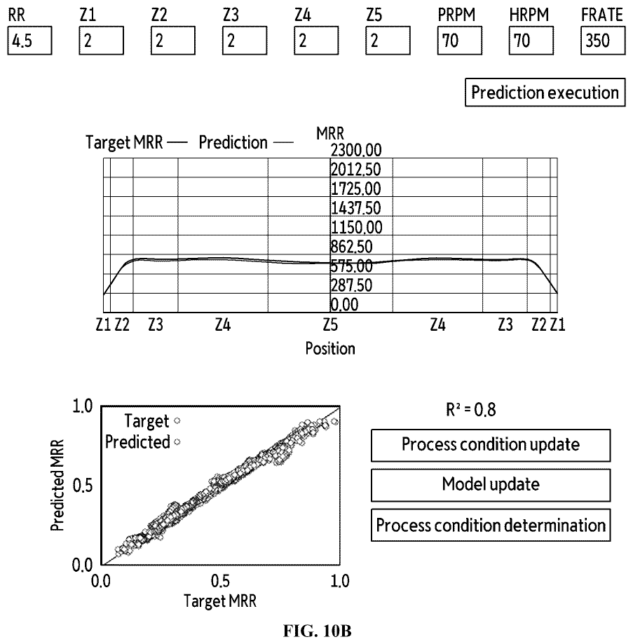

The input/output device 50 controls user input and output from user interface devices. For example, the input/output device 50 may include a keyboard or a monitor to receive information from a designer. In some embodiments, the process condition of the CMP process or the target MRR profile may be input using the input/output device 50, and the input process condition or target MRR profile may be used in the CMP simulation of the CMP tool 34. In addition, a processing process and a processing result of the CMP tool 34 may be displayed as a graphical user interface (GUI) through the input/output device 50. An example graphical user interface related thereto is described below with reference to FIG. 10.

The auxiliary memory device 70 is provided as a storage medium of the computing device. The auxiliary memory device 70 may non-temporarily store therein the application programs, an operating system image, and various data. The auxiliary memory device 70 may include a non-volatile memory such as a read only memory (ROM), an erasable programmable ROM (EPROM), an electrically erasable programmable ROM (EEPROM), a flash memory, or the like, a hard disk, a removable disk, a next-generation non-volatile memory such as a PRAM, a MRAM, a ReRAM, a FRAM, or the like, a NOR flash memory, or any type of a computer-readable recording medium well known in the art to which the present disclosure pertains.

A system interconnector 90 may be a system bus for providing a network inside the computing device. The processor 10, the working memory 30, the input/output device 50, and the auxiliary memory device 70 may be electrically connected to each other via the system interconnector 90 and may exchange data with each other. However, a configuration of the system interconnector 90 is not limited to the above description, and may further include arbitration means for efficient management.

FIG. 4 illustrates an artificial intelligence model for performing CMP simulation according to an example embodiment of the present disclosure. Referring to FIG. 4, the artificial intelligence model may be implemented as a neural network model including an input layer, an intermediate layer, and an output layer, each of which includes a plurality of neurons, and may receive a pressure of a retaining ring, a pressure onto each area of a wafer (e.g., Zone 1 pressure, Zone 2 pressure, etc.), a rotation speed of a platen, a rotation speed of a carrier (e.g., head speed), and a slurry flow rate as the process condition of the CMP process, and predict and output an MRR profile based on the received process condition. In the case of FIG. 4, it is shown that MRRs (MRR 1 to MRR 121) measured at a total of 121 measurement points are output.

The number of input neurons, the number of intermediate neurons, the number of intermediate layers, and the number of output neurons may be arbitrarily set, and a type of an activation function may be set to any one of sigmoid, tanh, ReLU, and Leaky ReLU. In order to train the artificial intelligence model, first, a target MRR value on an input process condition may be set, and an output MRR value on the input process condition may be calculated. Thereafter, an error between the output MRR value and the target MRR value may be calculated, and a connection strength between the intermediate layer and the output layer may be changed based on the calculated error. In addition, a connection strength between the input layer and the intermediate layer may be changed based on the error calculated on the intermediate layer. The above-described processes may be repeated until a preset learning rate is achieved on all training data. When the preset learning rate is achieved, the training of the artificial intelligence model may be terminated.

For example, the input data may include a process condition of the CMP process on a total of 80 patterns, 70 patterns among the 80 patterns may be used as patterns for training the AI model, the remaining patterns may be used as patterns for validation, and corresponding output data may include 121 MRR values on each of the 80 patterns. The artificial intelligence model trained as described above may be used to perform the CMP simulation of the CMP tool 34 as described above with reference to FIG. 3.

Although FIG. 4 is described based on the artificial intelligence model that receives the process condition of the CMP process and predicts and outputs the MRR profile, a configuration and training method of an artificial intelligence model that receives the MMR profile and outputs a corresponding process condition will also be similar to those described with reference to FIG. 4. In addition, the present disclosure is not limited to the configuration of the artificial intelligence model shown in FIG. 4, and the artificial intelligence model of the present disclosure may be implemented in another manner.

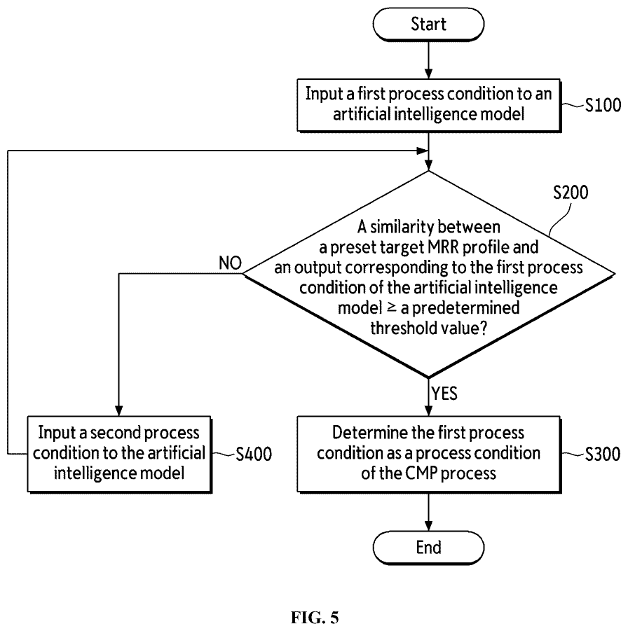

FIG. 5 is an example flowchart illustrating a CMP simulation method according to an embodiment. For reference, FIG. 5 and FIGS. 6 to 9, which will be described below, show steps/operations of the CMP simulation method performed in the computing device (specifically, the CMP tool 34) of FIG. 3. Accordingly, in the following descriptions, it may be understood that when a subject of a specific step/operation is omitted, the specific step/operation is performed in the computing device of FIG. 3.

In operation S100, a first process condition on the CMP process may be input to the artificial intelligence model. In this regard, the artificial intelligence model is a model trained to receive the process condition of the CMP process and predict and output the MRR profile based on the received process condition. In operation S200, a similarity between a preset target MRR profile and an output corresponding to the first process condition of the artificial intelligence model may be calculated, and may be compared with a preset threshold value.

For example, calculating the similarity between the target MRR profile and the output corresponding to the first process condition of the artificial intelligence model may correspond to calculating the prediction accuracy of the artificial intelligence model. In this case, calculating the prediction accuracy of the artificial intelligence model may include calculating a correlation coefficient or a R-squared value between the target MRR profile and the output corresponding to the first process condition of the artificial intelligence model.

When the similarity is equal to or greater than the predetermined threshold value (YES), the first process condition may be determined as the process condition of the CMP process in operation S300. On the other hand, when the similarity is smaller than the threshold value (NO), a second process condition different from the first process condition may be input to the artificial intelligence model in operation S400. After the operation S400, the similarity may be recalculated based on the output corresponding to the second process condition of the artificial intelligence model in operation S200, and subsequent operations may be repeated in the same manner as described above.

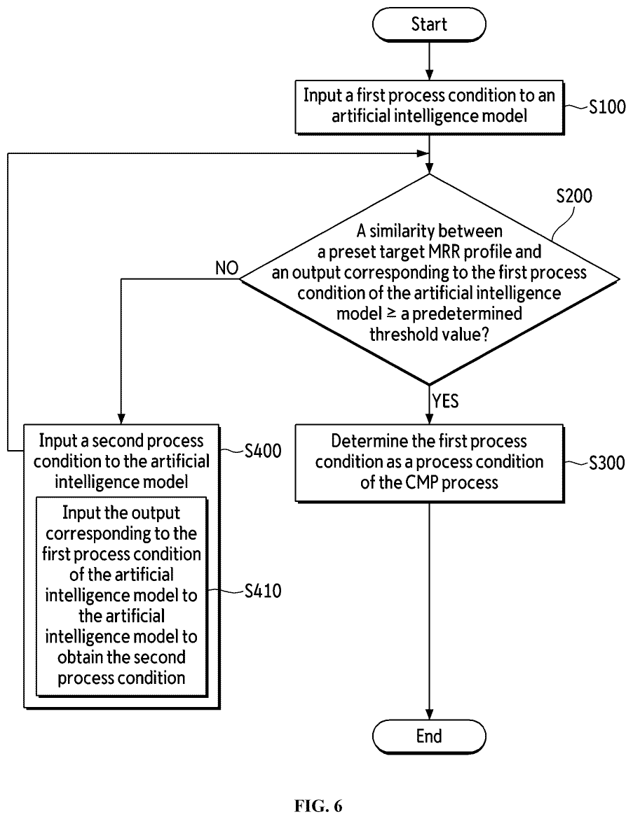

FIG. 6 is a flowchart specifically illustrating the operation S400 of inputting the second process condition of FIG. 5 into the artificial intelligence model. Referring to FIG. 6, in operation S410, an output corresponding to a first process condition of the artificial intelligence model may be input to the artificial intelligence model, and a second process condition determined such that the prediction accuracy is equal to or greater than a threshold value may be obtained.

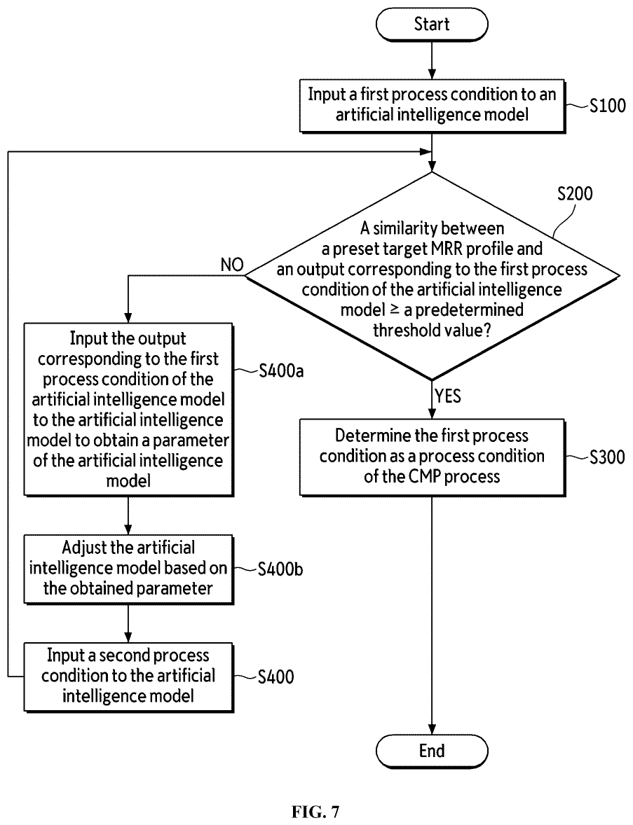

FIG. 7 is a flowchart illustrating an CMP simulation method according to another embodiment of the present disclosure. Referring to FIG. 7, after the operation S200, when the similarity is smaller than the threshold value (NO), the output corresponding to the first process condition of the artificial intelligence model may be input to the artificial intelligence model, and a parameter of the artificial intelligence model allowing the prediction accuracy to be equal to or greater than the threshold value may be obtained in step 400a. In operation S400b, the artificial intelligence model may be adjusted based on the obtained parameter.

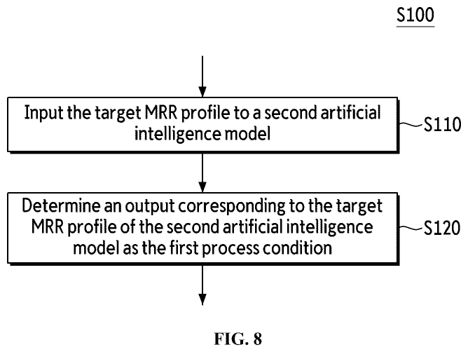

FIG. 8 is a flowchart specifically illustrating the operation S100 of inputting the first process condition of FIG. 5 into the artificial intelligence model. In FIG. 8, operation S100 is shown as including operations S110 and S120. Referring to FIG. 8, in operation S110, the target MRR profile may be input to the second artificial intelligence model trained to receive the MRR profile of the CMP process and to predict and output a process condition based on the received MRR profile. Thereafter, in operation S120, the output corresponding to the target MRR profile of the second artificial intelligence model may be determined as the first process condition.

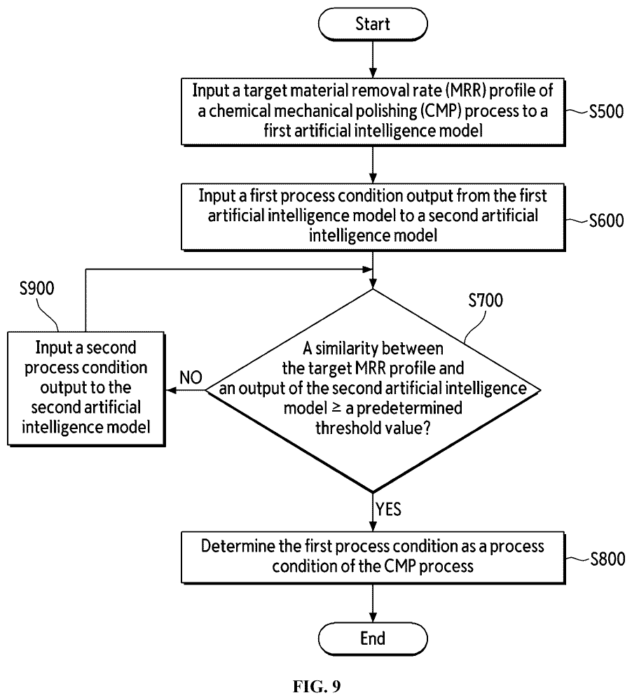

FIG. 9 is an example flowchart illustrating a CMP simulation method according to another embodiment of the present disclosure. Referring to FIG. 9, in operation S500, the target MRR profile of the CMP process may be input to the first artificial intelligence model. In this regard, the first artificial intelligence model is a model trained to receive the MRR profile of the CMP process and predict and output the process condition based on the received MMR profile. In operation S600, the first process condition output from the first artificial intelligence model may be input to the second artificial intelligence model. In this regard, the second AI model is a model trained to receive the process condition of the CMP process and predict and output the MRR profile, unlike the first AI model. In operation S700, a similarity between the target MRR profile and the output corresponding to the first process condition of the second AI model may be calculated. In addition, when the similarity is equal to or greater than the preset threshold value (YES), the first process condition may be determined as the process condition of the CMP process in operation S800. On the other hand, when the similarity is less than the preset threshold value (NO), a second process condition may be input to the second artificial intelligence model. For example, the second process condition may be an output of the adjusted first artificial intelligence model in response to receiving the target MRR profile. As described with reference to FIG. 5, the similarity between the target MRR profile and the output corresponding to the first process condition of the second artificial intelligence model may correspond to the prediction accuracy of the second artificial intelligence model. The embodiments as described above with reference to FIGS. 5 to 7 may be equally applied to the prediction accuracy.

FIGS. 10A and 10B illustrate an example graphical user interface (GUI) on which a CMP simulation method according to an embodiment of the present disclosure is performed. Referring to FIG. 10A, the user may input the number of input neurons, the number of intermediate layers, the number of intermediate neurons, the number of output neurons, the number of training patterns, and the number of validation patterns for training the artificial intelligence model, input a target learning rate, and input and select a momentum coefficient and an activation function through the graphical user interface. Thereafter, the user may input an input pattern and an output pattern for training, may start training of the artificial intelligence model via a training start button, and the training result (total number of training, total training error, total validation error, total accuracy) may be displayed.

Referring to FIG. 10B, after the training of the artificial intelligence model is completed through such a process, the user may input prediction data RR, Z1, Z2, Z3, Z4, Z5, PRPM, HRPM, and FRATE for the MRR profile. RR refers to the pressure of the retainer ring, each of Z1 to Z5 refers to the pressure on each of the zones of the wafer, PRPM refers to the rotational speed of the platen, HRPM refers to the rotational speed of the carrier, and FRATE refers to the slurry flow rate. Via a prediction button, the target MRR and the predicted MRR are displayed on one graph, and the prediction accuracy and the corresponding R-squared value may be displayed. When the R-squared value is smaller than the predetermined threshold value, the user may input a new process condition as an input via a process condition update button, and may adjust the parameter of the artificial intelligence model via a model update button and re-train the artificial intelligence model based on the adjusted parameter. When the R-squared value is equal to or greater than the preset threshold value, the user may determine the input process condition as the final process condition via a process condition determination button.

According to an embodiment of the present disclosure, the system and method of the present disclosure may stably secure the MRR profile desired by an operator in the CMP process. Specifically, according to an embodiment of the present disclosure, the stabilization of the CMP process may be achieved by optimizing the pressure on each of zones in the CMP equipment having a pressing structure, and the prediction result regarding the unknown process condition may be intuitively displayed. Furthermore, according to an embodiment of the present disclosure, the system and method of the present disclosure may predict the process condition regardless of a structure of the carrier head of various CMP equipment without being limited to specific CMP equipment. Thus, versatility of the system and method of the present disclosure may be secured.

In one example, the CMP simulation method according to an embodiment of the present disclosure may be executed in the computing device of FIG. 3. For example, the auxiliary memory device 70 of FIG. 3 may non-temporarily store therein one or more computer programs, and the computer programs may include one or more instructions that cause the processor 10 to perform operations/methods according to various embodiments of the present disclosure when being loaded into the working memory 30. That is, the processor 10 may perform an operation/method according to various embodiments of the disclosure by executing one or more loaded instructions.

For example, the computer program non-temporarily stored in the auxiliary memory device 70 may include instructions for inputting a first process condition on a chemical mechanical polishing (CMP) process to an artificial intelligence model, wherein the artificial intelligence model has been trained to receive a process condition of the CMP process and predict and output a material removal rate (MRR) profile based on the received process condition; calculating a similarity between a preset target MRR profile and an output corresponding to the first process condition of the artificial intelligence model; in response to that the similarity is equal to or greater than a predetermined threshold value, determining the first process condition as a process condition of the CMP process; and in response to that the similarity is smaller than the threshold value, inputting a second process condition different from the first process condition to the artificial intelligence model.

Various embodiments of the present disclosure and the effects according to those embodiments have been mentioned above with reference to FIGS. 1 to 10B. The effects according to the technical idea of the present disclosure are not limited to the effects as mentioned above, and other effects not mentioned may be clearly understood by those skilled in the art from the above descriptions.

All the components that constitute the embodiment of the present disclosure are described as being combined with each other or operating in combination with each other. However, the present disclosure is not necessarily limited to this embodiment. In other words, within the scope of the purpose of the present disclosure, all of the components may operate in a selective combination manner of at least two thereof with each other.

Although the operations are shown as being executed in a specific order in the drawings, it should not be understood that the operations should be performed in the specific order as shown or in a sequential order or that all illustrated operations should be performed to obtain the desired result.

Although embodiments of the present disclosure have been described with reference to the accompanying drawings, embodiments of the present disclosure are not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

1. A chemical mechanical polishing (CMP) simulation method performed by a computing device, the method comprising:
inputting a first process condition on a CMP process to an artificial intelligence model, wherein the artificial intelligence model has been trained to receive a process condition of the CMP process and predict and output a material removal rate (MRR) profile based on the received process condition;
calculating a similarity between a preset target MRR profile and an output corresponding to the first process condition of the artificial intelligence model;
in response to calculating that the similarity is equal to or greater than a predetermined threshold value, determining the first process condition as the process condition of the CMP process; and
in response to calculating that the similarity is smaller than the predetermined threshold value, inputting a second process condition different from the first process condition to the artificial intelligence model.

2. The CMP simulation method of claim 1,
wherein the similarity corresponds to a prediction accuracy of the artificial intelligence model, and
wherein the calculating of the similarity includes calculating a correlation coefficient between the target MRR profile and the output corresponding to the first process condition of the artificial intelligence model.

3. The CMP simulation method of claim 2, wherein the inputting of the second process condition to the artificial intelligence model includes:
in response to calculating that the similarity is smaller than the predetermined threshold value, inputting the output corresponding to the first process condition of the artificial intelligence model to the artificial intelligence model to obtain the second process condition allowing the prediction accuracy to be equal to or greater than the predetermined threshold value.

4. The CMP simulation method of claim 2, further comprising:
in response to calculating that the similarity is smaller than the predetermined threshold value, inputting the output corresponding to the first process condition of the artificial intelligence model to the artificial intelligence model to obtain a parameter of the artificial intelligence model allowing the prediction accuracy to be equal to or greater than the predetermined threshold value; and
adjusting the artificial intelligence model based on the obtained parameter.

5. The CMP simulation method of claim 1, wherein the process condition of the CMP process includes a pressure of a retaining ring, a pressure on each of a plurality of zones of a wafer, a rotation speed of a platen, a rotation speed of a carrier, and a slurry flow rate.

6. The CMP simulation method of claim 1, further comprising controlling a CMP apparatus connected to the computing device under the determined process condition.

7. The CMP simulation method of claim 1,
wherein the artificial intelligence model is a first artificial intelligence model, and
wherein the inputting of the first process condition to the artificial intelligence model includes:
inputting the target MRR profile to a second artificial intelligence model, wherein the second artificial intelligence model has been trained to receive an MRR profile of the CMP process and predict and output a process condition based on the received MMR profile; and
determining an output corresponding to the target MRR profile of the second artificial intelligence model as the first process condition.

8. A chemical mechanical polishing (CMP) simulation system comprising:
a processor; and
a memory for storing instructions therein,
wherein when the instructions are executed by the processor, the instructions cause the processor to:
input a first process condition on a CMP process to an artificial intelligence model, wherein the artificial intelligence model has been trained to receive a process condition of the CMP process and predict and output a material removal rate (MRR) profile based on the received process condition;
calculate a similarity between a preset target MRR profile and an output corresponding to the first process condition of the artificial intelligence model;
in response to calculating that the similarity is equal to or greater than a predetermined threshold value, determine the first process condition as the process condition of the CMP process; and
in response to calculating that the similarity is smaller than the predetermined threshold value, input a second process condition different from the first process condition to the artificial intelligence model.

9. The CMP simulation system of claim 8,
wherein the similarity corresponds to a prediction accuracy of the artificial intelligence model, and
wherein the calculating of the similarity includes calculating a correlation coefficient between the target MRR profile and the output corresponding to the first process condition of the artificial intelligence model.

10. The CMP simulation system of claim 9, wherein the inputting of the second process condition to the artificial intelligence model includes:
in response to calculating that the similarity is smaller than the predetermined threshold value, inputting the output corresponding to the first process condition of the artificial intelligence model to the artificial intelligence model to obtain the second process condition allowing the prediction accuracy to be equal to or greater than the predetermined threshold value.

11. The CMP simulation system of claim 9, wherein when the instructions are executed by the processor, the instructions further cause the processor to:
in response to calculating that the similarity is smaller than the predetermined threshold value, input the output corresponding to the first process condition of the artificial intelligence model to the artificial intelligence model to obtain a parameter of the artificial intelligence model allowing the prediction accuracy to be equal to or greater than the predetermined threshold value; and
adjust the artificial intelligence model based on the obtained parameter.

12. The CMP simulation system of claim 8, wherein the process condition of the CMP process includes a pressure of a retaining ring, a pressure on each of a plurality of zones of a wafer, a rotation speed of a platen, a rotation speed of a carrier, and a slurry flow rate.

13. The CMP simulation system of claim 8,
wherein the artificial intelligence model is a first artificial intelligence model, and
wherein the inputting of the first process condition to the artificial intelligence model includes:
inputting the target MRR profile to a second artificial intelligence model, wherein the second artificial intelligence model has been trained to receive an MRR profile of the CMP process and predict and output a process condition based on the received MMR profile; and
determining an output corresponding to the target MRR profile of the second artificial intelligence model as the first process condition.

14. A non-transitory computer-readable medium storing therein a computer program, wherein when the computer program is executed by a processor, the processor is configured to:
input a first process condition on a chemical mechanical polishing (CMP) process to an artificial intelligence model, wherein the artificial intelligence model has been trained to receive a process condition of the CMP process and predict and output a material removal rate (MRR) profile based on the received process condition;
calculate a similarity between a preset target MRR profile and an output corresponding to the first process condition of the artificial intelligence model;
in response to calculating that the similarity is equal to or greater than a predetermined threshold value, determine the first process condition as the process condition of the CMP process; and
in response to calculating that the similarity is smaller than the predetermined threshold value, input a second process condition different from the first process condition to the artificial intelligence model.

15. The non-transitory computer-readable medium of claim 14,
wherein the similarity corresponds to a prediction accuracy of the artificial intelligence model, and
wherein the calculating of the similarity includes calculating a correlation coefficient between the target MRR profile and the output corresponding to the first process condition of the artificial intelligence model.

16. The non-transitory computer-readable medium of claim 15, wherein the inputting of the second process condition to the artificial intelligence model includes:
in response to calculating that the similarity is smaller than the predetermined threshold value, inputting the output corresponding to the first process condition of the artificial intelligence model to the artificial intelligence model to obtain the second process condition allowing the prediction accuracy to be equal to or greater than the predetermined threshold value.

17. The non-transitory computer-readable medium of claim 15, wherein when the computer program is executed by the processor, the processor is further configured to:
in response to calculating that the similarity is smaller than the predetermined threshold value, input the output corresponding to the first process condition of the artificial intelligence model to the artificial intelligence model to obtain a parameter of the artificial intelligence model allowing the prediction accuracy to be equal to or greater than the predetermined threshold value; and
adjust the artificial intelligence model based on the obtained parameter.

18. The non-transitory computer-readable medium of claim 14, wherein the process condition of the CMP process includes a pressure of a retaining ring, a pressure on each of a plurality of zones of a wafer, a rotation speed of a platen, a rotation speed of a carrier, and a slurry flow rate.

19. The non-transitory computer-readable medium of claim 14,
wherein the artificial intelligence model is a first artificial intelligence model, and
wherein the inputting of the first process condition to the artificial intelligence model includes:
inputting the target MRR profile to a second artificial intelligence model, wherein the second artificial intelligence model has been trained to receive an MRR profile of the CMP process and predict and output a process condition based on the received MMR profile; and
determining an output corresponding to the target MRR profile of the second artificial intelligence model as the first process condition.

20. The non-transitory computer-readable medium of claim 14,
wherein each of an operation of inputting the first process condition to the artificial intelligence model, an operation of calculating a prediction accuracy of the artificial intelligence model, an operation of determining the first process condition as the process condition of the CMP process, and an operation of inputting the second process condition to the artificial intelligence model is performed on a graphical user interface (GUI), and
wherein the graphical user interface includes a value of the first process condition, a value of a parameter of the artificial intelligence model, a value of the output corresponding to the first process condition of the artificial intelligence model, a graph representing the MRR profile corresponding to the output, and a graph representing the prediction accuracy of the artificial intelligence model.

21. (canceled)
